(19) United States
(12) Patent Application Publication
(10) Pub. No.: US 2014/0008678 A1
(43) Pub. Date: Jan. 9, 2014

(54) LIGHT EMITTING DIODE DEVICE

(71) Applicant: LEXTAR ELECTRONICS CORPORATION, Hsinchu (TW)

(72) Inventors: Yun-Yi Tien, Hsinchu City (TW); Jian-Chin Liang, Hsinchu City (TW)

(73) Assignee: LEXTAR ELECTRONICS CORPORATION, Hsinchu (TW)

(21) Appl. No.: 13/740,802

(22) Filed: Jan. 14, 2013

(30) Foreign Application Priority Data
Jul. 6, 2012 (TW) 101124452

(51) Int. Cl. H01L 33/58

(52) U.S. Cl. CPC H01L 33/58
USPC 257/98

(57) ABSTRACT

A light emitting diode device includes a substrate, a light emitting diode chip, an optical lens and an adhesive interface layer. The light emitting diode chip is electrically connected with the substrate. The optical lens has an accommodation cavity to enclose the light emitting diode chip on the substrate, wherein the accommodation cavity includes a micro diffusion structure on an inner wall thereof. The adhesive interface layer is filled within the accommodation cavity of the optical lens.

### RELATED APPLICATIONS

The present application is based on, and claims priority from, Taiwan Application Serial Number 101124452, filed on Jul. 6, 2012, the disclosure of which is hereby incorporated by reference herein in its entirety.

### BACKGROUND

1. Field of Invention

The present invention relates to a light emitting diode device. More particularly, the present invention relates to a light emitting diode device equipped with an optical lens.

2. Description of Related Art

Light emitting diode devices are more widely used on the illumination, and there is a gradual trend to replace traditional incandescent light bulbs and mercury lamp. With the upgrading of the standard of living, increasingly high demands are generated for modern lighting quality. Some light-emitting diodes with optical lens design came into being in order to achieve the lighting quality requirements while more and more optical lens design are applied to the light emitting diode device.

There are several different ways used in the manufacture of the optical lens for the emitting diode device. A conventional method for forming optical lens is to dispense a plastic material directly on the light emitting diode chip, and to employ surface tension to control the shape of the optical lens, but this method does not provide a precise shaping control on the size and shape of the optical lens, and plastic material hardening time is too long to cause a slower production.

Furthermore, another manufacturing method of the optical lens is to design a mold according to the desired optical lens, fill a plastic material in a recess of the mold, use the recess of the molded optical lens to enclose the light emitting diode chip, and finally removing the mold off the hardened optical lens. This method needs an exclusive mold of higher costs, and plastic material hardening time is too long to cause a slower production.

In view of the difficulties encountered by the formation of optical lens in the production, there is a need for a more suitable optical lens forming method for mass production.

### SUMMARY

It is therefore an objective of the present invention to provide an optical lens forming method for mass production

In accordance with the foregoing and other objectives of the present invention, a light emitting diode device is provided to include a substrate, a light emitting diode chip, an optical lens and an adhesive interface layer. The light emitting diode chip is electrically connected with the substrate. The optical lens has an accommodation cavity to enclose the light emitting diode chip on the substrate, wherein the accommodation cavity includes a micro diffusion structure on an inner wall thereof. The adhesive interface layer is filled within the accommodation cavity of the optical lens.

According to another embodiment disclosed herein, the micro diffusion structure includes a plurality of cone-shaped members.

According to another embodiment disclosed herein, the cone-shaped members are triangular pyramids, square pyramids or circular cones.

According to another embodiment disclosed herein, a refractive index of the adhesive interface layer is between a refractive index of the light emitting diode chip and a refractive index of the optical lens.

According to another embodiment disclosed herein, the accommodation cavity is a hemispherical, sawtooth, square, rectangular, pyramidal, conical, cylindrical, or pie-shaped cavity.

According to another embodiment disclosed herein, the substrate is a single-sided or double-sided electrically conductive substrate.

According to another embodiment disclosed herein, the optical lens is made from a thermoplastic material.

According to another embodiment disclosed herein, the light emitting diode chip is electrically connected with the substrate by a conductive wire.

According to another embodiment disclosed herein, the light emitting diode chip is electrically connected with the substrate by a flip-chip way.

According to another embodiment disclosed herein, the optical lens has a hemispherical profile.

Thus, the light emitting diode device disclosed herein has an optical lens design, which can be more suitable for mass production. The present invention provides an optical lens equipped with an accommodation cavity, into which an adhesive is filled, to couple with the light emitting diode chip. The light emitting diode device of this invention does not need compressing molding to manufacture its optical lens so as to reduce the cost of product development and hours. In addition, because the optical lens is manufactured by injection molding, a thermoplastic material at lower costs and of more varied optical lens shape can be chosen to improve the optical performance.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a cross-sectional view of a light emitting diode device according to a first embodiment of this invention;

FIG. 2 illustrates a cross-sectional view of a light emitting diode device according to a second embodiment of this invention;

FIG. 3 illustrates a cross-sectional view of a light emitting diode device according to a third embodiment of this invention;

FIG. 4 illustrates a cross-sectional view of a light emitting diode device according to a fourth embodiment of this invention;

FIG. 5 illustrates a cross-sectional view of a light emitting diode device according to a fifth embodiment of this invention;

FIG. 6 illustrates a cross-sectional view of a light emitting diode device according to a sixth embodiment of this invention;

FIG. 7 illustrates a cross-sectional view of a light emitting diode device according to a seventh embodiment of this invention;

FIG. 8 illustrates a perspective view of a cone-shaped member of a micro diffusion structure in a light emitting diode device according to an eighth embodiment of this invention;

FIG. 9 illustrates a perspective view of a cone-shaped member of a micro diffusion structure in a light emitting diode device according to a ninth embodiment of this invention; and

FIG. 10 illustrates a perspective view of a cone-shaped member of a micro diffusion structure in a light emitting diode device according to a tenth embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

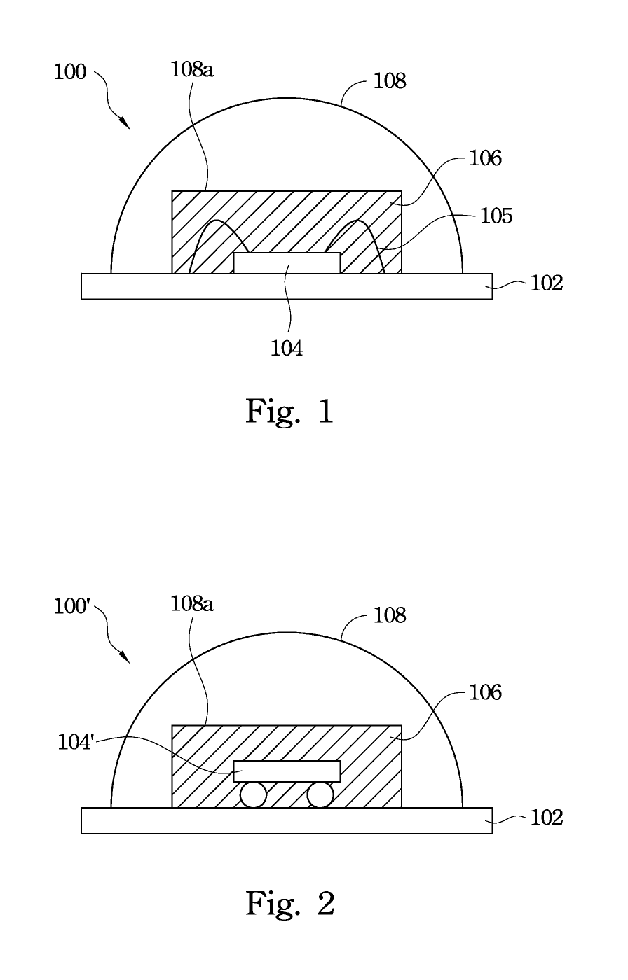

FIG. 1 illustrates a cross-sectional view of a light emitting diode device according to a first embodiment of this invention. The light emitting diode device 100 includes a substrate 102, a light emitting diode chip 104 and an optical lens 108. The optical lens 108 is formed by injection molding a hemispherical profile, which has an accommodation cavity 108a to enclose the light emitting diode chip 104 on the substrate 102. When the optical lens 108 is mounted over the light emitting diode chip 104, the accommodation cavity 108a is filled with an adhesive interface layer 106 and coupled with the light emitting diode chip 104 and the substrate 102. The adhesive interface layer 106 may take some time to cure, but the adhesive interface layer 106 is smaller than the whole optical lens 108 and thus has a shorter curing time than the whole optical lens 108 has. The adhesive interface layer 106 can be a thermosetting adhesive material or a light curing adhesive material by heating or illumination to accelerate the hardening. In addition, a refractive index of the adhesive interface layer 106 is preferably between a refractive index of the light emitting diode chip 104 and a refractive index of the optical lens 108 in order to increase the light extraction rate of the whole light emitting diode device. The substrate 102 may be a single-sided or double-sided electrically conductive substrate. The optical lens 108 may be made from a thermoplastic material or other applicable materials in the injection molding process. In this embodiment, the light emitting diode chip 104 is electrically connected with the substrate 102 by a conductive wire 105, and the accommodation cavity 108a may be a square, rectangular cavity.

FIG. 2 illustrates a cross-sectional view of a light emitting diode device according to a second embodiment of this invention. The light emitting diode device 100′ of the second embodiment is different from the light emitting diode device 100 of the first embodiment in packaging a different light emitting diode chip 104′. The light emitting diode chip 104′ is electrically connected with the substrate 102 by a flip-chip way, rather than by a conductive wire 105 as used in the light emitting diode chip 104.

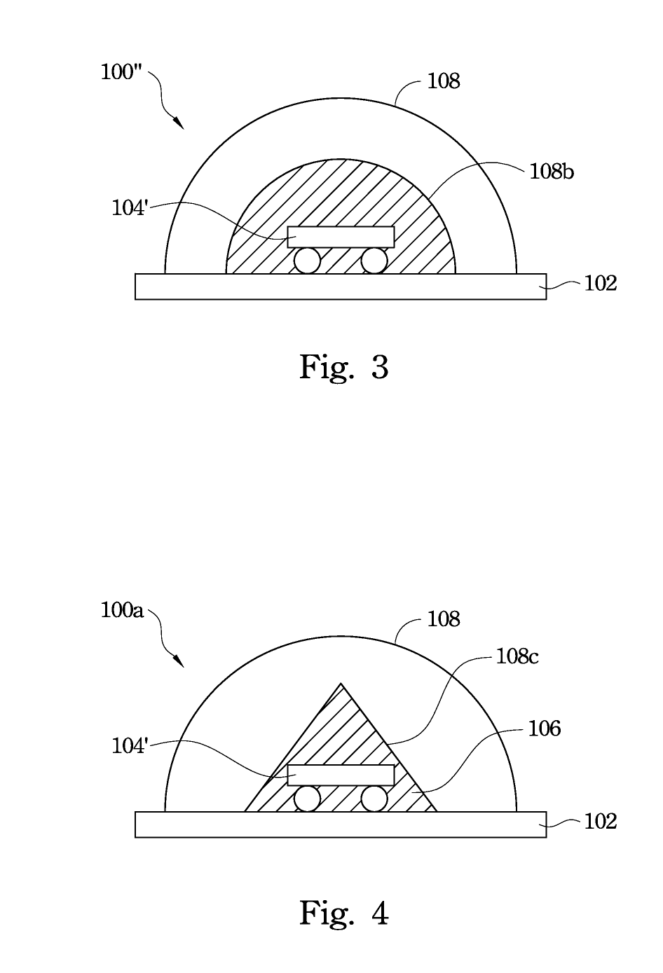

FIG. 3 illustrates a cross-sectional view of a light emitting diode device according to a third embodiment of this invention. The light emitting diode device 100″ of the third embodiment is different from the light emitting diode device of the first and second embodiments in a different shaped accommodation cavity of the optical lens 108. In this embodiment, the accommodation cavity 108b of the optical lens 108 is a hemispherical cavity.

FIG. 4 illustrates a cross-sectional view of a light emitting diode device according to a fourth embodiment of this invention. The light emitting diode device 100a of the fourth embodiment is different from the light emitting diode device of the first, second and third embodiments in a different shaped accommodation cavity of the optical lens 108. In this embodiment, the accommodation cavity 108c of the optical lens 108 is a pyramidal or conical cavity.

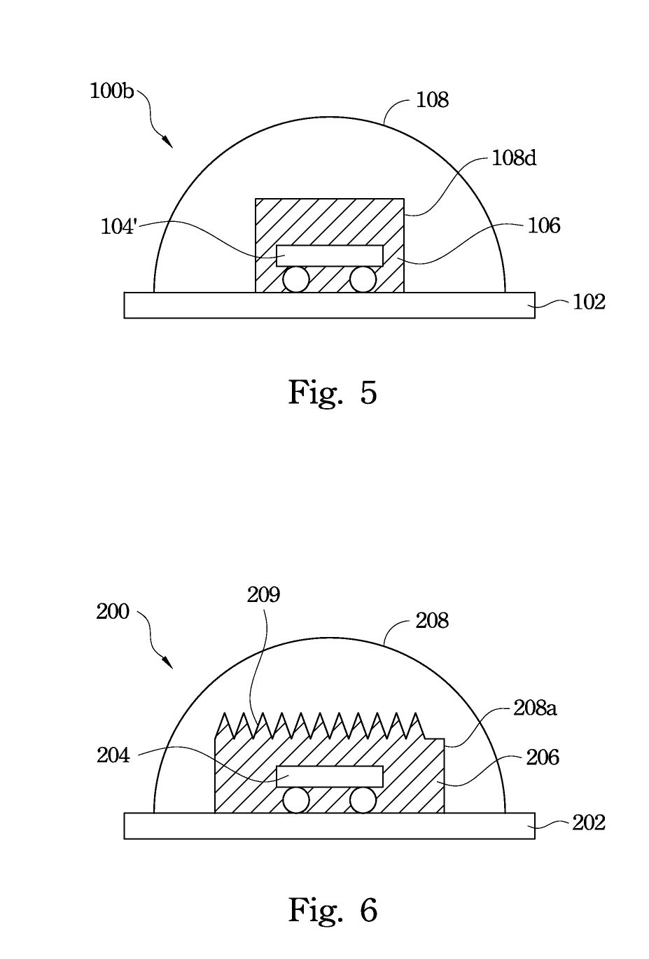

FIG. 5 illustrates a cross-sectional view of a light emitting diode device according to a fifth embodiment of this invention. The light emitting diode device 100b of the fifth embodiment is different from the light emitting diode device of the first, second, third and fourth embodiments in a different shaped accommodation cavity of the optical lens 108. In this embodiment, the accommodation cavity 108d of the optical lens 108 is a cylindrical or pie-shaped cavity.

FIG. 6 illustrates a cross-sectional view of a light emitting diode device according to a sixth embodiment of this invention. The light emitting diode device 200 of the sixth embodiment is different from the light emitting diode device of the first, second, third, fourth and fifth embodiments in an additional function of the accommodation cavity of the optical lens 208. In this embodiment, the accommodation cavity 208a of the optical lens 208 is equipped with a micro diffusion structure 209 so as to increase the uniformity of light. The micro diffusion structure 209 includes multiple cone-shaped members, and all cone-shaped members have their tip ends directed towards an emitting surface, e.g., an upper surface, of the light emitting diode chip 204. The light emitting diode device 200 includes a substrate 202, a light emitting diode chip 204 and an optical lens 208. The optical lens 208 is formed by injection molding a hemispherical profile, which has a sawtooth accommodation cavity 108a to enclose the light emitting diode chip 204 on the substrate 202. When the optical lens 208 is mounted over the light emitting diode chip 204, the accommodation cavity 208a is filled with an adhesive interface layer 206 and then coupled with the light emitting diode chip 204 and the substrate 202. The adhesive interface layer 206 may take some time to cure, but the adhesive interface layer 206 is smaller than the whole optical lens 208 and thus has a shorter curing time than the whole optical lens 208 has. The adhesive interface layer 206 can be a thermosetting adhesive material or a light curing adhesive material by heating or illumination to accelerate the hardening. In addition, a refractive index of the adhesive interface layer 206 is preferably between a refractive index of the light emitting diode chip 204 and a refractive index of the optical lens 208 in order to increase the light extraction rate of the whole light emitting diode device. The substrate 202 may be a single-sided or double-sided electrically conductive substrate. The optical lens 208 may be made from a thermoplastic material or other applicable materials in the injection molding process. In this embodiment, the light emitting diode chip 204 is electrically connected with the substrate 202 by a flip-chip way. In addition, the accommodation cavity of the optical lens 208 is not limited to the shape illustrated in FIG. 6, and can be the various accommodation cavities illustrated in the first, second, third, fourth and fifth embodiments plus the micro diffusion structure.

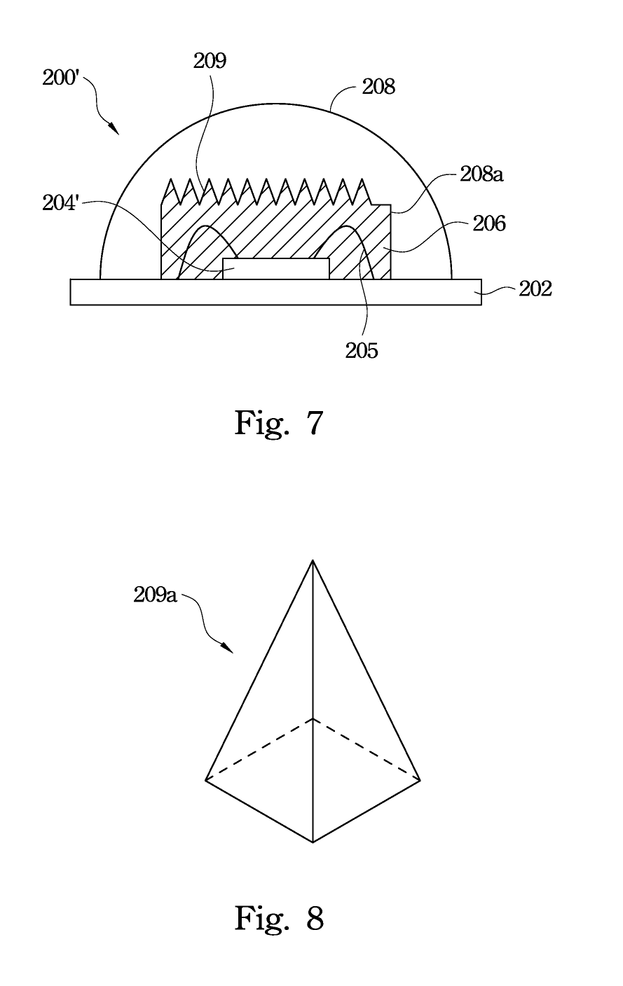

FIG. 7 illustrates a cross-sectional view of a light emitting diode device according to a seventh embodiment of this invention. The light emitting diode device 200′ of the seventh embodiment is different from the light emitting diode device 200 of the sixth embodiment in packaging a different light emitting diode chip 204′. The light emitting diode chip 204′ is electrically connected with the substrate 202 by a conductive wire 205, rather than by a flip-chip way as used in the light emitting diode chip 204.

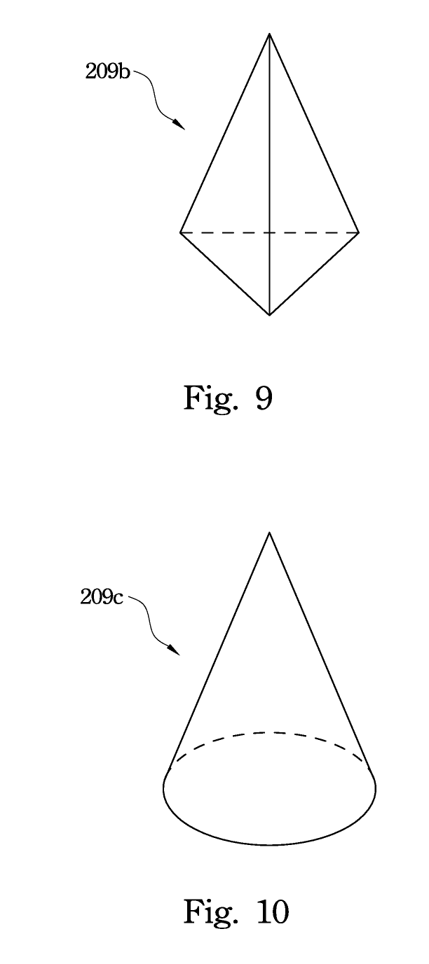

FIG. 8 illustrates a perspective view of a cone-shaped member of a micro diffusion structure in a light emitting diode device according to an eighth embodiment of this invention, FIG. 9 illustrates a perspective view of a cone-shaped member of a micro diffusion structure in a light emitting diode device according to a ninth embodiment of this invention; and FIG. 10 illustrates a perspective view of a cone-shaped member of a micro diffusion structure in a light emitting diode device according to a tenth embodiment of this invention. In FIG. 8, the cone-shaped member of the micro diffusion structure is a square pyramid 209a. In FIG. 9, the cone-shaped member of the micro diffusion structure is a triangular pyramid 209b. In FIG. 10, the cone-shaped member of the micro diffusion structure is a circular cone 209c. The emitting light from the light emitting diode chip 204 can be even more uniform after passing through the cone-shaped members of the micro diffusion structure 209 as illustrated in FIG. 6.

According to the above-discussed embodiments, the light emitting diode device disclosed herein has an optical lens design, which can be more suitable for mass production. The present invention provides an optical lens equipped with an accommodation cavity, into which an adhesive is filled, to couple with the light emitting diode chip. The light emitting diode device of this invention does not need compressing molding to manufacture its optical lens so as to reduce the cost of product development hours. In addition, because the optical lens is manufactured by injection molding, a thermoplastic material of lower costs and more varied optical lens shapes can be chosen to improve the optical performance.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode device comprising:
a substrate;
a light emitting diode chip electrically connected with the substrate;
an optical lens having an accommodation cavity to enclose the light emitting diode chip on the substrate, wherein the accommodation cavity comprises a micro diffusion structure on an inner walls thereof; and
an adhesive interface layer filled within the accommodation cavity of the optical lens.

2. The light emitting diode device of claim 1, wherein the micro diffusion structure comprises a plurality of cone-shaped members.

3. The light emitting diode device of claim 2, wherein the cone-shaped members are triangular pyramids, square pyramids or circular cones.

4. The light emitting diode device of claim 1, wherein a refractive index of the adhesive interface layer is between a refractive index of the light emitting diode chip and a refractive index of the optical lens.

5. The light emitting diode device of claim 1, wherein the accommodation cavity is a hemispherical, sawtooth, square, rectangular, pyramidal, conical, cylindrical, or pie-shaped cavity.

6. The light emitting diode device of claim 1, wherein the substrate is a single-sided or double-sided electrically conductive substrate.

7. The light emitting diode device of claim 1, wherein the optical lens is made from a thermoplastic material.

8. The light emitting diode device of claim 1, wherein the light emitting diode chip is electrically connected with the substrate by a conductive wire.

9. The light emitting diode device of claim 1, wherein the light emitting diode chip is electrically connected with the substrate by a flip-chip way.

10. The light emitting diode device of claim 1, wherein the optical lens has a hemispherical profile.
